(19) United States
(12) Patent Application Publication
(10) Pub. No.: US 2001/0008785 A1
(43) Pub. Date: Jul. 19, 2001

(54) Method of forming a bottom electrode of a capacitor in a dynamic random access memory cell

(76) Inventors: Wei-Wu Liao, Taipei Hsien (TW); Chien-Li Kuo, Hsin-Chu City (TW)

Correspondence Address: WINSTON HSU, 5 F, No. 389, Fu-Ho Road, Yung-Ho City, Taipei Hsien, 234, TW

(21) Appl. No.: 09/764,398

(22) Filed: Jan. 19, 2001

Related U.S. Application Data
(62) Division of application No. 09/359,649, filed on Jul. 26, 1999.

(51) Int. Cl. H01L 21/8242

(52) U.S. Cl. 438/244

(57) ABSTRACT

A method of forming a bottom electrode of a capacitor in a dynamic random access memory cell. The bottom electrode of the capacitor is formed on a semiconductor wafer, the semiconductor wafer includes a silicon substrate, and a first dielectric layer positioned on the silicon substrate having a contact hole extending down to the silicon substrate. The method includes the following steps: a first polysilicon layer is formed in the contact hole as a conductive plug. A second dielectric layer is then formed on the first dielectric layer. A vertical opening is formed in the second dielectric layer that extends down to the contact hole, and a pillar-shaped second polysilicon layer is formed in the opening, that the bottom end of the second polysilicon layer is electrically connected to the first polysilicon layer in the contact hole. Finally, a predetermined thickness of the second dielectric layer is removed so that the top end of the second polysilicon layer protrudes from the second dielectric layer, the top end of the second polysilicon being used as the bottom electrode of the capacitor. The bottom end of the second polysilicon layer inlayed within the vertical opening of the second dielectric layer fixes the bottom electrode of the capacitor on the semiconductor wafer so as to prevent the bottom electrode of the capacitor from collapsing during further processing.

### BACKGROUND OF THE INVENTION

1. Field of the Invention

The present invention relates to a method of forming a bottom electrode of a capacitor, and more particularly, to a method of forming a bottom electrode of a capacitor in a dynamic random access memory cell.

2. Description of the Prior Art

In semiconductor processing, a dynamic random access memory cell is composed of a metal oxide semiconductor (MOS) transistor and a capacitor. The capacitor is designed on a semiconductor wafer and comprises a top electrode layer, a bottom electrode layer and an isolating layer for separating the two electrode layers at a predetermined distance. When a voltage is applied to the two electrode layers, charge is stored between them and thus capacitance is generated.

Please refer to FIG. 1. FIG. 1 is a sectional schematic diagram of a bottom electrode 20 of a capacitor in a dynamic random access memory cell according to the prior art. The bottom electrode 20 of the capacitor in a dynamic random access memory cell is positioned on a semiconductor wafer 10. The semiconductor wafer 10 comprises a silicon substrate 12, a dielectric layer 14 positioned on the silicon substrate 12, a contact hole 16 positioned on the dielectric layer extending down to the silicon substrate 12, and a first polysilicon layer 18 positioned in the contact hole 16. The bottom electrode 20 is a pillar-shaped second polysilicon layer positioned on the dielectric layer 14 and electrically connected to the first polysilicon layer 18.

Because the pillar-shaped second polysilicon layer is not inlayed within the semiconductor wafer 10, the bottom electrode 20 may easily collapse during further processing. This decreases the yield of semiconductor products.

### SUMMARY OF THE INVENTION

It is therefore a primary objective of the present invention to provide a bottom electrode of a capacitor in a dynamic random access memory cell, which can be fixed on a semiconductor wafer so as to prevent the bottom electrode from collapsing during further processing.

In a preferred embodiment, the present invention provides a method of forming a bottom electrode of a capacitor in a dynamic random access memory cell. The bottom electrode of the capacitor is formed on a semiconductor wafer, the semiconductor wafer includes a silicon substrate, and a first dielectric layer positioned on the silicon substrate having a contact hole extending down to the silicon substrate. The method includes the following steps: a first polysilicon layer is formed in the contact hole as a conductive plug. A second dielectric layer is then formed on the first dielectric layer. A vertical opening is formed in the second dielectric layer that extends down to the contact hole, and a pillar-shaped second polysilicon layer is formed in the opening, that the bottom end of the second polysilicon layer is electrically connected to the first polysilicon layer in the contact hole. Finally, a predetermined thickness of the second dielectric layer is removed so that the top end of the second polysilicon layer protrudes from the second dielectric layer, the top end of the second polysilicon being used as the bottom electrode of the capacitor. The bottom end of the second polysilicon layer inlayed within the vertical opening of the second dielectric layer fixes the bottom electrode of the capacitor on the semiconductor wafer so as to prevent the bottom electrode of the capacitor from collapsing during further processing.

It is an advantage of the present invention that the bottom end of the second polysilicon layer is inlayed within the vertical opening of the second dielectric layer and is fixed to the bottom electrode of the capacitor on the semiconductor wafer. This prevents the bottom electrode of the capacitor from collapsing during further processing.

This and other objective of the present invention will no doubt become obvious to those of ordinary skill in the art after having read the following detailed description of the preferred embodiment which is illustrated in the various figures and drawings.

### BRIEF DESCRIPTION OF THE DRAWINGS

FIG. 1 is a sectional schematic diagram of a bottom electrode of a capacitor in a dynamic random access memory cell according to the prior art.

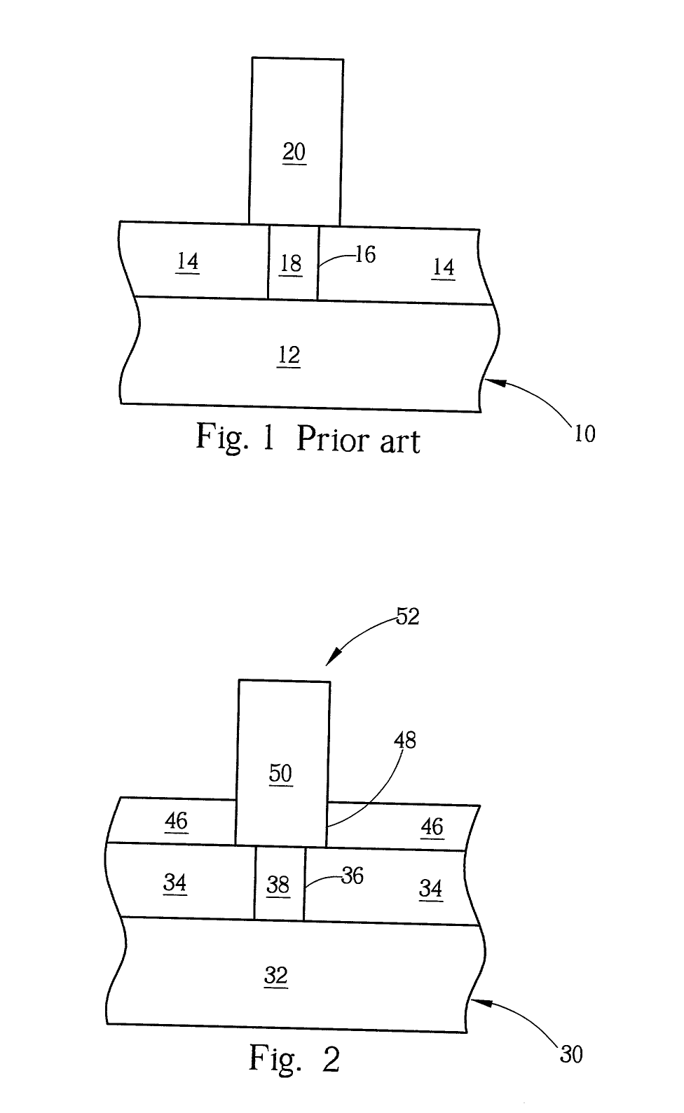

FIG. 2 is a sectional schematic diagram of a bottom electrode of a capacitor in a dynamic random access memory cell according to the prevent invention.

FIG. 3 to FIG. 7 are schematic diagrams of a method of forming the bottom electrode shown in FIG. 2.

### DETAILED DESCRIPTION OF THE PREFERRED EMBODIMENT

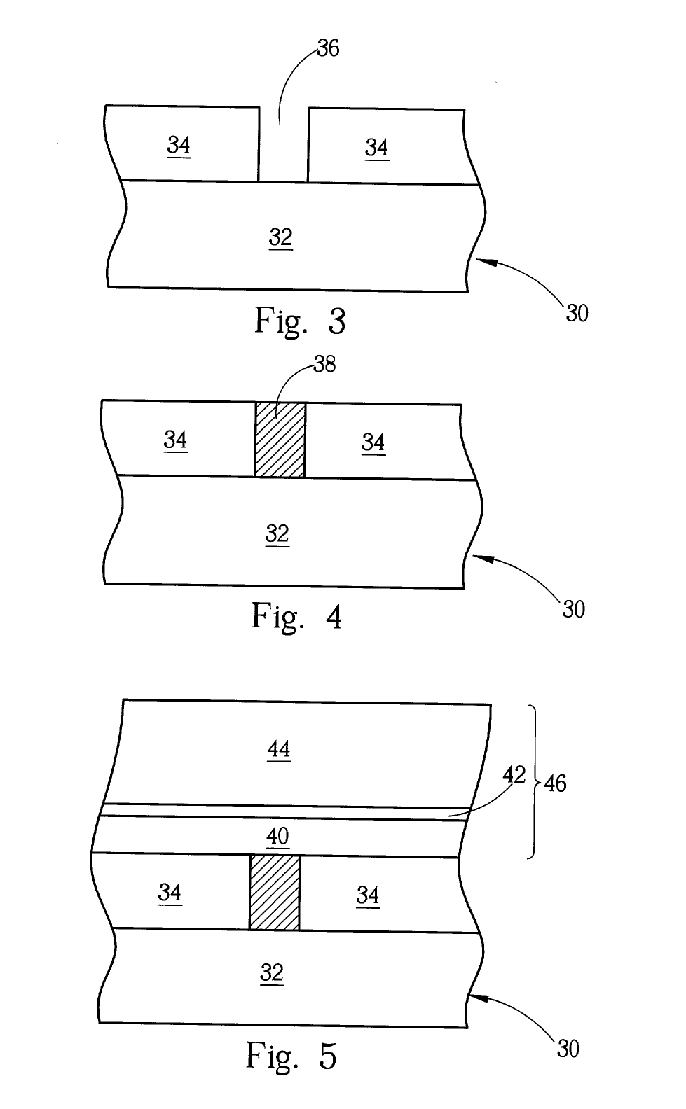

Please refer to FIG. 2. FIG. 2 is a sectional schematic diagram of a bottom electrode 52 of a capacitor in a dynamic random access memory cell according to the prevent invention. A bottom electrode 52 of a capacitor in a dynamic random access memory cell is positioned on a semiconductor wafer 30. The semiconductor wafer 30 comprises a silicon substrate 32, a first dielectric layer 34 positioned on the silicon substrate 32, and a second dielectric layer 46 positioned on the first dielectric layer 34. The first dielectric layer 34 comprises a contact hole 36 extending down to the silicon substrate 32. Also, the semiconductor wafer 30 comprises a first polysilicon layer 38 positioned in the contact hole 36, and a pillar-shaped second polysilicon layer 50. The bottom end of the second polysilicon layer 50 is perpendicularly inlayed within the vertical opening 48 of the second dielectric layer 46 and electrically connected to the first polysilicon layer 38. The top end of the second polysilicon layer 50 protrudes from the second dielectric layer 46 as the bottom electrode 52 of the capacitor.

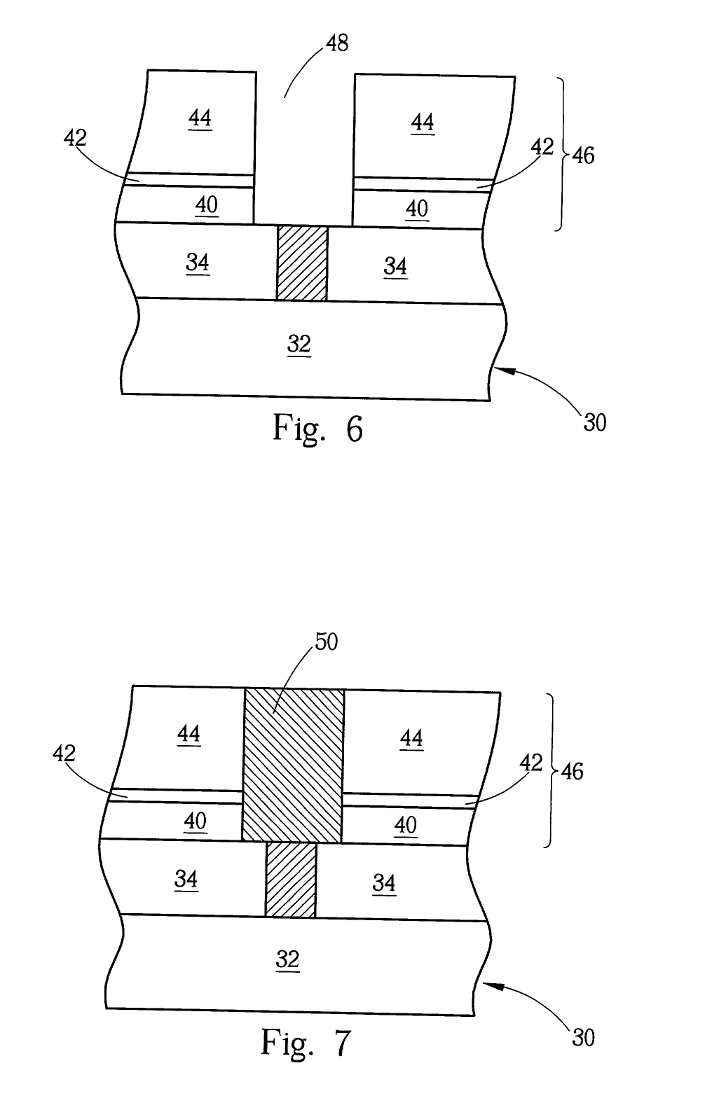

Please refer to FIG. 3 to FIG. 7 FIG. 3 to FIG. 7 are schematic diagrams of a method of forming the bottom electrode 52 shown in FIG. 2. The bottom electrode 52 is formed on the semiconductor wafer 30. As shown in FIG. 3, the semiconductor wafer 30 comprises the silicon substrate 32, and the first dielectric layer 34 positioned on the silicon substrate 32 and comprising a contact hole 36 extending down to the silicon substrate 32. Firstly, the first polysilicon layer 38 is formed on the first dielectric layer 34, which fills the contact hole 36. Then a chemical mechanical polishing (CMP) process or an etching back process is performed to completely remove the first polysilicon layer 38 covering the first dielectric layer 34 and to level off the top end of the first polysilicon layer 38 remaining in the contact hole 36. This makes the first polysilicon layer 38 flush with the surface of the first dielectric layer 34 as shown in FIG. 4. The first polysilicon layer 38 positioned in the contact hole 36 is used as a conductive plug.

Next, a bottom dielectric layer 40, a stop-etch layer 42 and a sacrifice layer 44 are sequentially formed as the second dielectric layer 46 on the first dielectric layer 34 by using a chemical vapor deposition (CVD) process as shown in FIG. 5. Both the bottom dielectric layer 40 and the sacrifice layer 46 are formed of silicon oxide. The stop-etch layer 42 is formed of silicon nitride or silicon-oxy-nitride to prevent removal of the bottom dielectric layer 40 during subsequent removal of the sacrifice layer 44. Then, an opening hole 48 is formed in the second dielectric layer 46 that extends down to the contact hole 36 as shown in FIG. 6.

Next, the second polysilicon layer 50 is formed on the second dielectric layer 46 and fills the vertical opening 48. Then, a chemical mechanical polishing (CMP) process or an etching back process is performed to completely remove the second polysilicon layer 50 from the top of the second dielectric layer 46 and to level off the top end of the second polysilicon layer 50 remaining in the vertical opening 48. This makes the second polysilicon layer 50 flush with the surface of the second dielectric layer 46 as shown in FIG. 7. The second polysilicon layer 50 is formed as a pillar-shaped structure inlayed within the vertical opening 48 with its bottom electrically connected to the first polysilicon layer 38.

Finally, a wet-etching process or a dry-etching process is performed to remove the sacrifice layer 44 so that the top end of the second polysilicon layer 50 protrudes from the second dielectric layer 46. The second polysilicon layer 50 protruding from the stop-etch layer 42 is employed as the bottom electrode 52.

In the method of forming the bottom electrode 52, the pillar-shaped second polysilicon layer 50 is formed in the vertical opening 48 of the second dielectric layer 46, and then the sacrifice layer is removed. This results in the top end of the second polysilicon layer 50 protruding from the stop-etch layer 42, and the bottom end becoming inlayed within the vertical opening 48. This fixes the bottom electrode 52 on the semiconductor wafer 30 and prevents the bottom electrode 52 from collapsing during further processing.

Compared to the prior bottom electrode 20 of the capacitor, in the bottom electrode 52 of the capacitor of the present invention, the top end of the pillar-shaped second polysilicon layer 50 protruding from the second dielectric layer 46 is used as the bottom electrode 52. The bottom end of the second polysilicon layer 50 is inlayed within the vertical opening 48 of the second dielectric layer 46 so as to fix the bottom electrode 52 on the semiconductor wafer 30 and prevent the bottom electrode 52 from collapsing during further processing.

Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method of forming a bottom electrode of a capacitor in a dynamic random access memory cell, the bottom electrode of the capacitor being formed on a semiconductor wafer, the semiconductor wafer comprising:
a silicon substrate; and
a first dielectric layer positioned on the silicon substrate comprising a contact hole extending down to the silicon substrate;
the method comprising:
forming a first polysilicon layer in the contact hole as a conductive plug;
forming a second dielectric layer on the first dielectric layer;
forming a vertical opening in the second dielectric layer that extends down to the contact hole;
forming a pillar-shaped second polysilicon layer in the opening, the bottom end of the second polysilicon layer being electrically connected to the first polysilicon layer in the contact hole; and
removing a predetermined thickness of the second dielectric layer so that the top end of the second polysilicon layer protrudes from the second dielectric layer, the top end of the second polysilicon being used as the bottom electrode of the capacitor;
wherein the bottom end of the second polysilicon layer inlayed within the vertical opening of the second dielectric layer fixes the bottom electrode of the capacitor on the semiconductor wafer so as to prevent the bottom electrode of the capacitor from collapsing during further processing.

2. The method of claim 1 wherein the method of forming the first polysilicon layer comprises the following steps:
forming the first polysilicon layer on the first dielectric layer which fills the contact hole of the first dielectric layer; and
performing a chemical mechanical polishing (CMP) process or an etching back process to completely remove the first polysilicon layer covered on top of the first dielectric layer and to level off the top end of the first polysilicon layer remained in the contact hole so that it is flush with the surface of the first dielectric layer.

3. The method of claim 1 wherein the method of forming the second polysilicon layer comprises the following steps:
forming the second polysilicon layer on the second dielectric layer which fills the opening of the second dielectric layer; and
performing a chemical mechanical polishing (CMP) process or an etching back process to completely remove the second polysilicon layer covered on top of the second dielectric layer and to level off the top end of the second polysilicon layer remained in the opening so that it is flush with the surface of the second dielectric layer.

4. The method of claim 1 wherein the second dielectric layer comprises a bottom dielectric layer positioned on the first dielectric layer, an stop-etch layer positioned on the bottom dielectric layer, and a sacrifice layer positioned on the stop-etch layer, the sacrifice layer being removed when the predetermined thickness of the second dielectric layer is removed, and the stop-etch layer being used to prevent the bottom dielectric layer from being removed when removing the sacrifice layer.

5. The method of claim 1 wherein the method of removing the predetermined thickness of the second dielectric layer employs a wet-etching process or a dry-etching process.
